(19) United States
(12) Patent Application Publication
(10) Pub. No.: US 2025/0117033 A1
(43) Pub. Date: Apr. 10, 2025

(54) LOW DROPOUT REGULATOR AND CAPACITOR COMPENSATION METHOD

(71) Applicant: Realtek Semiconductor Corporation, Hsinchu (TW)

(72) Inventors: Yi FENG, Hsinchu (TW); Chuan Chu LIU, Hsinchu (TW)

(21) Appl. No.: 18/772,295

(22) Filed: Jul. 15, 2024

(30) Foreign Application Priority Data
Oct. 4, 2023 (TW) 112138174

(51) Int. Cl. G05F 1/56

(52) U.S. Cl. CPC G05F 1/56

(57) ABSTRACT

A low dropout regulator (LDO) comprising an amplifier, a buffer circuit, an output circuit, a first compensation capacitor and a second compensation capacitor is provided. The buffer circuit comprises an input terminal coupled to an output terminal of the amplifier. The output circuit comprises an input terminal coupled to an output terminal of the buffer circuit, and comprises an output terminal for outputting a voltage. The first compensation capacitor is coupled between the output terminal of the output circuit and an internal cascade node of the amplifier, and configured to separate a first pole frequency of a Bode plot of the LDO from a power supply rejection ratio corner frequency. The second compensation capacitor is coupled between the input terminal of the buffer circuit and an input power source, and configured to separate a second pole frequency and a third pole frequency of the Bode plot of the LDO.

### RELATED APPLICATIONS

This application claims priority to Taiwan Application Serial Number 112138174, filed on Oct. 4, 2023, which is herein incorporated by reference in its entirety.

### BACKGROUND

### Technical Field

The present disclosure relates to a low dropout regulator (LDO). More particularly, the present disclosure relates to a low dropout regulator and a capacitor compensation method having an improved power supply rejection ratio (PSRR).

### Description of Related Art

Low dropout regulator is a type of linear DC voltage regulator. Since the low dropout regulator is able to operate under smaller output-to-input voltage differences and has advantages of smaller output noise and smaller size, the low dropout regulator is often applied in various circuits.

For a low dropout regulator, the power supply rejection ratio (PSRR) represents its ability to suppress noise. Conventional low dropout regulators usually use two methods to improve the PSRR. The first method is to increase the number of compensation capacitors in a low dropout regulator, but this method will significantly increase the area occupied by the low dropout regulator. The second method is to perform compensation through additional circuits, but this method will increase the power consumption of the system and may even cause latch-up. Consequently, how to effectively improve the PSRR of a low dropout regulator is one of the topics in this field.

### SUMMARY

A low dropout regulator is provided in the present disclosure. The low dropout regulator comprises an amplifier, a buffer circuit, an output circuit, a first compensation capacitor and a second compensation capacitor. The amplifier comprises a non-inverting input terminal, an inverting input terminal, an internal cascade node and an output terminal. The buffer circuit comprises an input terminal and an output terminal, wherein the input terminal of the buffer circuit is coupled to the output terminal of the amplifier. The output circuit comprises an input terminal and an output terminal, wherein the input terminal of the output circuit is coupled to the output terminal of the buffer circuit, and the output terminal of the output circuit is configured to output an output voltage. The first compensation capacitor is coupled between the output terminal of the output circuit and the internal cascade node of the amplifier, and is configured to separate a first pole frequency in a Bode plot of the low dropout regulator and a power supply rejection ratio corner frequency of the low dropout regulator. The second compensation capacitor is coupled between the input terminal of the buffer circuit and an input power source, and is configured to separate a second pole frequency and a third pole frequency in the Bode plot of the low dropout regulator, so as to make the low dropout regulator operate stably.

A low dropout regulator is provided in the present disclosure. The low dropout regulator comprises an amplifier, a buffer circuit, an output circuit, a first compensation capacitor and a second compensation capacitor. The amplifier comprises a non-inverting input terminal, an inverting input terminal, an internal cascade node and an output terminal. The buffer circuit comprises an input terminal and an output terminal, wherein the input terminal of the buffer circuit is coupled to the output terminal of the amplifier. The output circuit comprises an input terminal and an output terminal, wherein the input terminal of the output circuit is coupled to the output terminal of the buffer circuit, and the output terminal of the output circuit is configured to output an output voltage. The first compensation capacitor is coupled between the output terminal of the output circuit and the internal cascade node of the amplifier, and is configured to separate a first pole frequency in a Bode plot of the low dropout regulator from a power supply rejection ratio corner frequency of the low dropout regulator. The second compensation capacitor is coupled between the input terminal and the output terminal of the buffer circuit, and is configured to separate a second pole frequency and a third pole frequency in the Bode plot of the low dropout regulator, so as to make the low dropout regulator operate stably.

A capacitor compensation method suitable for a low dropout regulator is provided in the present disclosure. The low dropout regulator comprises an amplifier and an output circuit, and the capacitor compensation method comprises: providing a buffer circuit in the low dropout regulator, wherein the buffer circuit comprises an input terminal and an output terminal, the input terminal of the buffer circuit is coupled to an output terminal of the amplifier, and the output terminal of the buffer circuit is coupled to an input terminal of the output circuit; providing a first compensation capacitor in the low dropout regulator, wherein the first compensation capacitor is coupled between an output terminal of the output circuit and an internal cascade node of the amplifier, and configured to separate a first pole frequency in a Bode plot of the low dropout regulator from a power supply rejection ratio corner frequency of the low dropout regulator; and providing a second compensation capacitor in the low dropout regulator, wherein the second compensation capacitor is coupled at the output terminal of the amplifier (as known as the input terminal of the buffer circuit), and configured to separate a second pole frequency and a third pole frequency in the Bode plot of the low dropout regulator, so as to make the low dropout regulator operate stably.

With the low dropout regulators and the capacitor compensation method of the present disclosure, the low dropout regulator can be compensated without significantly increasing its area and power consumption, thereby improving the PSRR of the low dropout regulator.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows.

FIG. 1 is a circuit diagram of a low dropout regulator in accordance with some embodiments of the present disclosure.

FIG. 2 is a circuit diagram of a low dropout regulator in accordance with some embodiments of the present disclosure.

FIG. 3 is a schematic diagram of a small-signal circuit model of a low dropout regulator in accordance with some embodiments of the present disclosure.

FIG. 4A is a schematic diagram of the power supply rejection ratio (PSRR) of low dropout regulators in accordance with some embodiments of the present disclosure.

FIG. 4B is a Bode plot of low dropout regulators in accordance with some embodiments of the present disclosure.

FIG. 5 is a flowchart of a capacitor compensation method in accordance with some embodiments of the present disclosure.

### DETAILED DESCRIPTION

Reference will now be made in detail to the present embodiments of the disclosure, examples of which are illustrated in the accompanying drawings.

In the present disclosure, when an element is referred to as “connected”, it may mean “electrically connected” or “optical connected”. When an element is referred to as “coupled”, it may mean “electrically coupled” or “optical coupled”. “Connected” or “coupled” can also be used to indicate that two or more components operate or interact with each other. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

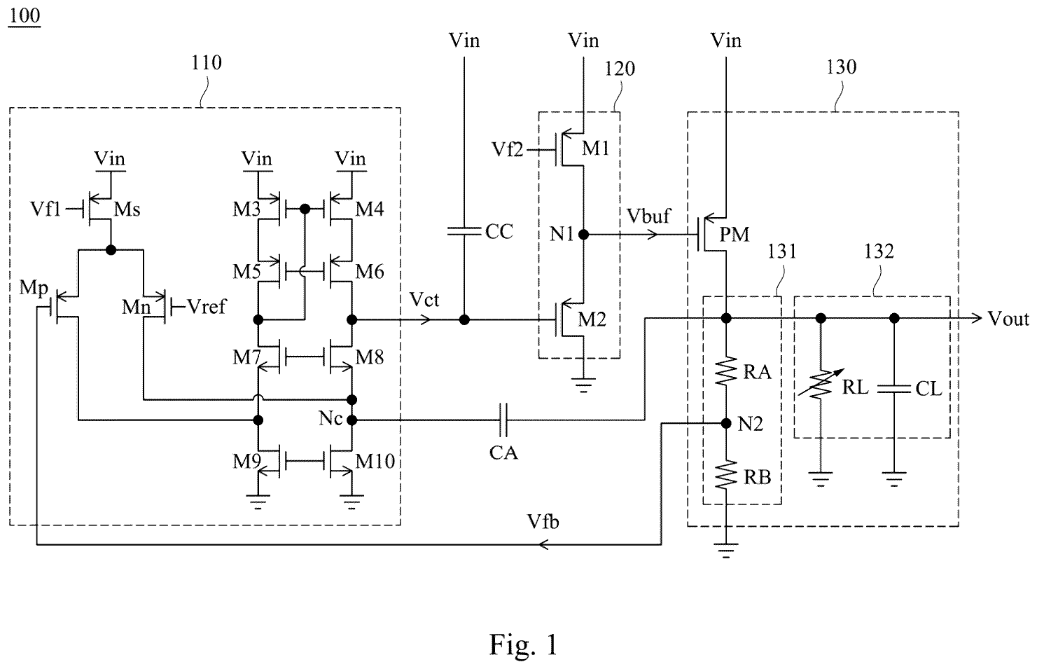

FIG. 1 is a circuit diagram of a low dropout regulator 100 in accordance with some embodiments of the present disclosure. In some embodiments, the low dropout regulator 100 comprises an amplifier 110, a buffer circuit 120, an output circuit 130, a compensation capacitor CA and a compensation capacitor CC.

In some embodiments, the amplifier 110 is an amplifier circuit formed by transistors Ms, Mp, Mn and M3-M10. The source terminals of the transistors M3 and M4 are configured to receive an input voltage from an input power source Vin, the gate terminals of the transistors M3 and M4 are coupled to each other, the drain terminal of the transistor M3 is coupled to the source terminal of the transistor M5, and the drain terminal of the transistor M4 is coupled to the source terminal of the transistor M6. The gate terminals of the transistors M5 and M6 are coupled to each other, the drain terminal of the transistor M5 is coupled to the drain terminal of the transistor M7 and the gate terminals of the transistors M3 and M4, and the drain terminal of the transistor M6 is coupled to the drain terminal of the transistor M8. The gate terminals of the transistors M7 and M8 are coupled to each other, the source terminal of the transistor M7 is coupled to the drain terminals of the transistors Mp and M9, and the source terminal of the transistor M8 is coupled to the drain terminal of the transistors Mn and M10. The gate terminals of the transistors M9 and M10 are coupled to each other, and the source terminals of the transistors M9 and M10 are configured to receive a ground voltage from a ground. In some embodiments, the node between the source terminal of the transistor M8 and the drain terminal of the transistor M10 is an internal cascade node Nc of the amplifier 110.

The source terminal of the transistor Ms is coupled to the input power source Vin, the gate terminal of the transistor Ms is configured to receive a reference voltage Vf1, and the drain terminal of the transistor Ms is coupled to the source terminals of the transistors Mp and Mn. The gate terminal of the transistor Mp is the non-inverting input terminal of the amplifier 110 and is coupled to the output circuit 130 for receiving a feedback voltage Vfb, and the drain terminal of the transistor Mp is coupled to the source terminal of the transistor M7. The gate terminal of the transistor Mn is the inverting input terminal of the amplifier 110 for receiving a reference voltage Vref, and the drain terminal of the transistor Mn is coupled to the source terminal of the transistor M8.

In addition, the amplifier 110 further comprises an output terminal located between the drain terminal of the transistor M6 and the drain terminal of the transistor M8 for outputting a control voltage Vct. The amplifier 110 is configured to output the control voltage Vct to the buffer circuit 120 at the output terminal based on the reference voltage Vref and the feedback voltage Vfb, so as to adjust the voltage output by the output circuit 130.

It should be noted that although the amplifier 110 in the present disclosure is shown as a folded cascode structure, it is not intended to limit the present disclosure. In some embodiments, the amplifier 110 may be implemented with a folded cascode structure, a telescopic structure, a two-stage structure, other amplifier structures or any combination thereof.

In some embodiments, the buffer circuit 120 comprises an input terminal and an output terminal. The input terminal of the buffer circuit 120 is coupled to the output terminal of the amplifier 110 and the compensation capacitor CC, and is configured to make the low dropout regulator 100 to operate stably. The buffer circuit 120 is configured to output a buffer voltage Vbuf to the output circuit 130 at its output terminal based on the control voltage Vct.

As shown in FIG. 1, in some embodiments, the buffer circuit 120 comprises transistors M1 and M2, wherein the source terminal of the transistor M1 is coupled to the input power source Vin, the drain terminal of the transistor M1 is coupled to the source terminal of the transistor M2, and the gate terminal of the transistor M1 is configured to receive a reference voltage Vf2. The drain terminal of the transistor M2 is configured to receive the ground voltage from the ground, and the gate terminal of the transistor M2 is configured to receive the control voltage Vct. The node N1 between the transistors M1 and M2 is coupled to the output circuit 130 for outputting the buffer voltage Vbuf.

It should be noted that although the buffer circuit 120 in FIG. 1 is shown as a source follower structure implemented with transistors M1 and M2, it is not intended to limit the present disclosure. The buffer circuit 120 in the present disclosure can be implemented with a super source follower structure, an enhanced super source follower structure, other similar circuit structures or any combination thereof.

In conventional low dropout regulators without a buffer circuit, since the output terminal of the amplifier is directly coupled to a power transistor, the transistors inside the amplifier tend to enter the linear region, thereby affecting the power supply rejection ratio (PSRR) of the low dropout regulators. The buffer circuit 120 of the low dropout regulator 100 in the present disclosure provides a voltage difference between the gate terminal and the source terminal of the transistor M2 between the output terminal of the amplifier 110 and the gate terminal of a power transistor PM, such that the transistors of the amplifier 110 are more likely to operate in the saturation region, thereby improving the PSRR of the low dropout regulator 100 when operating at low frequencies.

In some embodiments, the output circuit 130 comprises an input terminal and an output terminal, and comprises the power transistor PM, a voltage divider circuit 131 and a loading circuit 132. The input terminal of the output circuit 130 is coupled to the output terminal of the buffer circuit 120, and the output terminal of the output circuit 130 is configured to output an output voltage Vout.

The gate terminal of the power transistor PM is coupled to the input terminal of the output circuit 130 (i.e., the output terminal of the buffer circuit 120) for receiving the buffer voltage Vbuf. The source terminal of the power transistor PM is coupled to the input power source Vin, and the drain terminal of the power transistor PM is coupled to the voltage divider circuit 131, the loading circuit 132 and the output terminal of the output circuit 130.

The voltage divider circuit 131 is coupled to the drain terminal of the power transistor PM, the non-inverting input terminal of the amplifier 110 and the ground, and is configured to output the feedback voltage Vfb to the non-inverting input terminal of the amplifier 110 based on the output voltage Vout. In some embodiments, the voltage divider circuit 131 comprises a divider resistor RA and a divider resistor RB. The divider resistors RA and RB are coupled in series between the drain terminal of the power transistor PM and the ground, and the node N2 between the divider resistors RA and RB is coupled to the non-inverting input terminal of the amplifier 110. The feedback voltage Vfb is determined by the ratio of the resistance values between the divider resistors RA and RB.

In some embodiments, the loading circuit 132 comprises a loading resistor RL and a loading capacitor CL, wherein the loading resistor RL and the loading capacitor CL are coupled in parallel between the drain terminal of the power transistor PM and the ground.

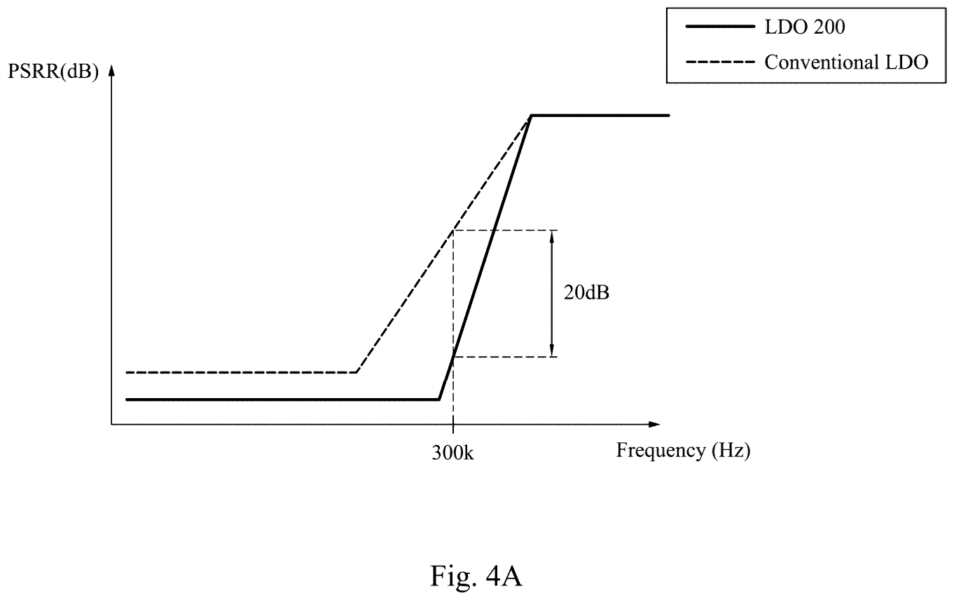

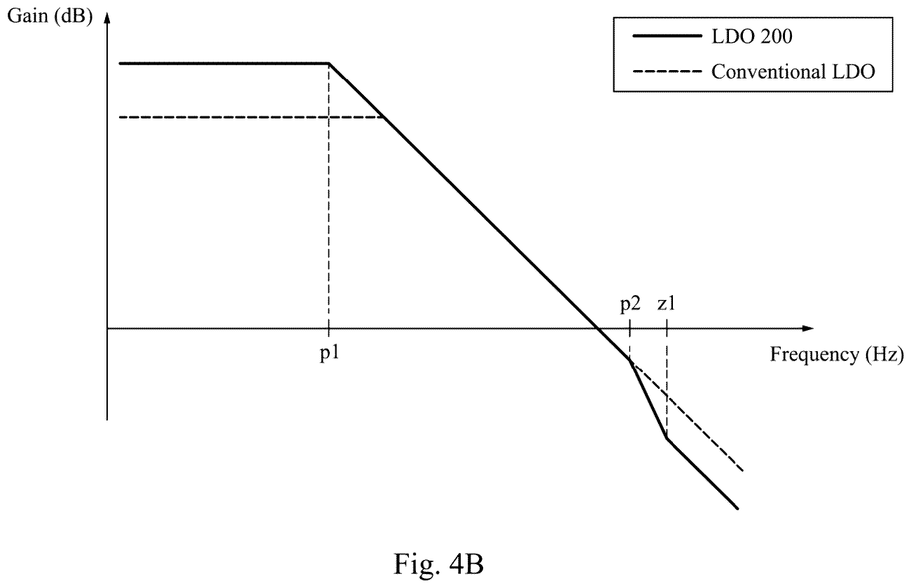

Under the Miller compensation used in conventional low dropout regulators, the power supply rejection ratio (PSRR) corner frequency of a low dropout regulator will be close to the first pole frequency in the Bode plot of the low dropout regulator, resulting in the two frequencies becoming unseparated. In the present disclosure, the compensation capacitor CA of the low dropout regulator 100 is coupled between the drain terminal of the power transistor PM and the internal cascade node Nc of the amplifier 110 for separating the PSRR corner frequency of the low dropout regulator 100 from the first pole frequency in the Bode plot of the low dropout regulator 100 (shown in FIG. 4A and FIG. 4B), so that the PSRR corner frequency will be higher than the first pole frequency in the Bode plot, and thus the PSRR of the low dropout regulator 100 will be improved.

It should be noted that the term “power supply rejection ratio (PSRR) corner frequency” in the present disclosure represents the corner point of the graph in the schematic diagram of the PSRR of a low dropout regulator (shown in FIG. 4A), and the term “first pole” represents the first corner point from low frequency to high frequency in the Bode plot of a low dropout regulator (shown in FIG. 4B).

By adding the compensation capacitor CA in the low dropout regulator 100, the PSRR corner frequency of the low dropout regulator 100 can be increased, so that the PSRR of the low dropout regulator 100 begins to rise at a higher frequency than the conventional low dropout regulators, thereby being able to be applied to a wider range of frequencies.

The compensation capacitor CC is coupled between the input terminal of the buffer circuit 120 and the input power source Vin for separating the second pole and the third pole in the Bode plot of the low dropout regulator 100.

It should be noted that the term “second pole” in the present disclosure represents the second corner point from low frequency to high frequency in the Bode plot of a low dropout regulator, and the term “third pole” represents the third corner point from low frequency to high frequency in the Bode plot of a low dropout regulator. Therefore, in some embodiments, the first pole frequency of the low dropout regulator 100 is lower than the second pole frequency, and the second pole frequency is lower than the third pole frequency.

In some embodiments, the first pole frequency in the Bode plot of the low dropout regulator 100 is determined by the capacitance of the compensation capacitor CA, the second pole frequency is determined by the capacitance of the compensation capacitor CC, and the third pole frequency is determined by the capacitance of the loading capacitor CL. If the capacitance of the compensation capacitor CC is too low, the second pole and the third pole will be too close, resulting in a complex pole phenomenon and an unstable operation of the low dropout regulator 100. Therefore, the compensation capacitor CC usually needs higher capacitance, thereby increasing the size of the compensation capacitor CC. The following paragraph will describe how to reduce the size of the compensation capacitor CC.

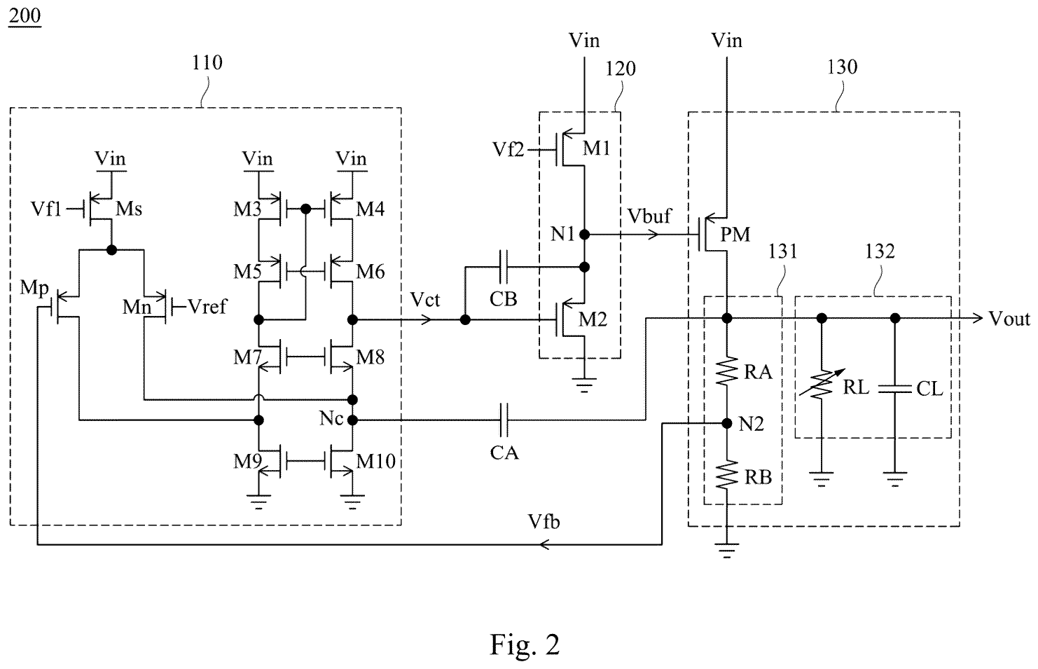

FIG. 2 is a circuit diagram of a low dropout regulator 200 in accordance with some embodiments of the present disclosure. The low dropout regulator 200 in FIG. 2 is similar to the low dropout regulator 100 in FIG. 1. For the sake of brevity, the following paragraphs will only focus on the differences.

In some embodiments, the low dropout regulator 200 in FIG. 2 does not comprise the compensation capacitor CC but further comprises a compensation capacitor CB. The compensation capacitor CB is coupled between the input terminal and the output terminal of the buffer circuit 120 (i.e., between the output terminal of the amplifier 110 and the input terminal of the output circuit 130), and is configured to separate the second pole frequency p2 and the third pole frequency p3 in Bode plot of the low dropout regulator 200.

Compared with the low dropout regulator 100 in FIG. 1, the connection method of the compensation capacitor CB in the low dropout regulator 200 in FIG. 2 has a capacitance amplification effect, which can make the second pole and the third pole in the Bode plot of the low dropout regulator 200 more easily separated, thereby maintaining the stable operation of the low dropout regulator 200.

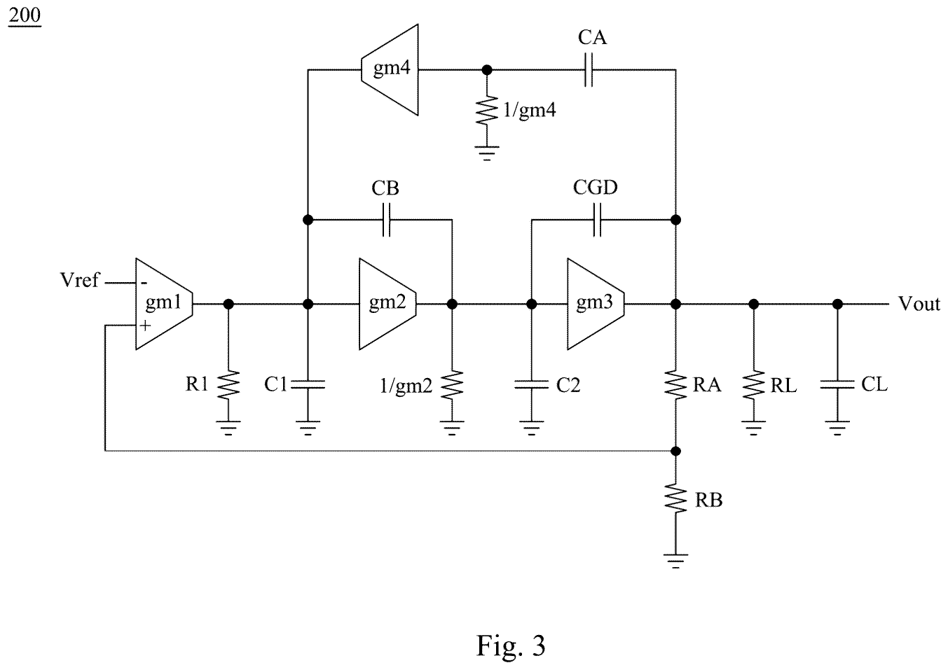

FIG. 3 is a schematic diagram of a small-signal circuit model of the low dropout regulator 200 in accordance with some embodiments of the present disclosure. By establishing a small-signal circuit model of the low dropout regulator 200, the first pole frequency p1, the second pole frequency p2 and the first zero point frequency z1 in the Bode plot of the low dropout regulator 200 can be obtained (as shown in FIG. 4B). The first pole frequency p1, the second pole frequency p2 and the first zero point frequency z1 can be respectively expressed by the following Formula 1, Formula 2 and Formula 3:

$$p 1 = \frac{1}{2 π \times R 1 \times C A \times g m 3 \times R L} \qquad Formula 1$$

$$p 2 \approx \frac{g m 2}{2 π \times C B \times ( 1 + \frac{C G D}{C A} )} \qquad Formula 2$$

$$z 1 = \frac{g m 4}{C A + C B \times \frac{g m 4}{g m 2}} \qquad Formula 3$$

In Formula 1, Formula 2 and Formula 3, “R1” represents the equivalent resistance of the output terminal of the amplifier 110, “CA” represents the capacitance of the compensation capacitor CA, “CB” represents the capacitance of the compensation capacitor CB, “CGD” represents the equivalent capacitance between the gate terminal and the drain terminal of the power transistor PM, “gm2” represents the transconductance of the transistor M2 of the buffer circuit 120, and “gm3” represents the transconductance of the power transistor PM. In FIG. 3, “gm1” represents the transconductance of the input pair of the amplifier 110, and “gm4” represents the transconductance from the compensation capacitor CA to the output terminal of the amplifier 110.

In order to explain the differences in the PSRR and the Bode plot between the low dropout regulator 200 of the present disclosure and conventional low dropout regulators, please refer to FIG. 4A and FIG. 4B. FIG. 4A is a schematic diagram of the PSRR of the low dropout regulator 200 (shown as a solid line) and a conventional low dropout regulator (shown as a dashed line) in accordance with some embodiments of the present disclosure.

The smaller the PSRR of a low dropout regulator, the better it operates. In the embodiment of FIG. 4A, the frequency at which the PSRR of the conventional low dropout regulator begins to rise is lower than the frequency at which the PSRR of the low dropout regulator 200 begins to rise. In other words, the low dropout regulator 200 can maintain better performance in a wider frequency range than the conventional low dropout regulator. In addition, at the same frequency, the low dropout regulator 200 also has a lower PSRR than the conventional low dropout regulator. Take the embodiment of FIG. 4A as an example, at a frequency of 300 kHz, the PSRR of the low dropout regulator 200 is 20 dB lower than the PSRR of the conventional low dropout regulator.

FIG. 4B is Bode plots of the low dropout regulator 200 and a conventional low dropout regulator in accordance with some embodiments of the present disclosure. As shown in FIG. 4B, since the low dropout regulator 200 comprises the compensation capacitor CA, the low dropout regulator 200 can adjust its first pole frequency p1 in the Bode plot to achieve different gain curves. In addition, since the low dropout regulator 200 comprises the compensation capacitor CB, the second pole frequency p2, the first zero point frequency z1 and the third pole frequency (not shown) in the Bode plot can also be adjusted, so that the low dropout regulator 200 can operate more stably.

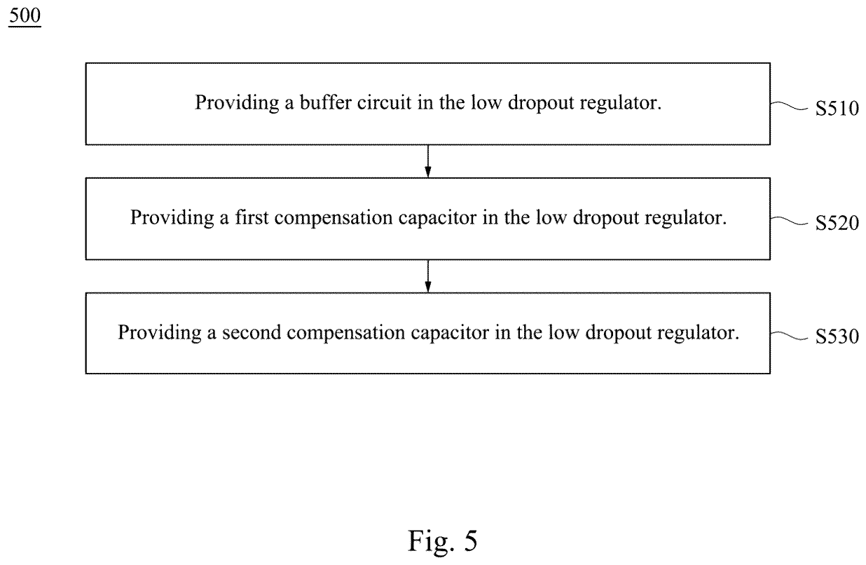

FIG. 5 is a flowchart of a capacitor compensation method 500 in accordance with some embodiments of the present disclosure. In some embodiments, the capacitor compensation method 500 comprises steps S510, S520 and S530.

In step S510, a buffer circuit (e.g., the buffer circuit 120) is provided in a low dropout regulator (e.g., the low dropout regulator 200), wherein the buffer circuit comprises an input terminal and an output terminal, the input terminal of the buffer circuit is coupled to an output terminal of an amplifier (e.g., the amplifier 110) of the low dropout regulator, and the output terminal of the buffer circuit is coupled to an input terminal of an output circuit (e.g., the output circuit 130) of the low dropout regulator.

In step S520, a first compensation capacitor (e.g., the compensation capacitor CA) is provided in the low dropout regulator, wherein the first compensation capacitor is coupled between an output terminal of the output circuit and an internal cascade node of the amplifier to for separating a first pole frequency in a Bode plot of the low dropout regulator and a power supply rejection ratio corner frequency of the low dropout regulator.

In step S530, a second compensation capacitor (e.g., the compensation capacitor CB or the compensation capacitor CC) is provided in the low dropout regulator, wherein the second compensation capacitor is coupled at the output terminal of the amplifier (as known as the input terminal of the buffer circuit) for separating a second pole frequency and a third pole frequency in the Bode plot of the low dropout regulator, so as to make the low dropout regulator operate stably.

It should be noted that the number and order of steps in the capacitor compensation method 500 in the present disclosure are only examples, and are not intended to limit the present disclosure. The other number and order of steps in the capacitor compensation method 500 are within the scope of the present disclosure. In some embodiments, steps S520 and S530 may be performed synchronously. In some embodiments, step S530 may be performed earlier than step S520.

In conclusion, compared with conventional low dropout regulators, the low dropout regulators 100, 200 and the low dropout regulators implemented through the capacitor compensation method 500 provided in the present disclosure can separate the first pole frequency p1 in the Bode plot from the PSRR corner frequency, so as to operate in a wider frequency range and increase the stability of operation. In addition, compared with conventional low dropout regulators, the buffer circuit 120 and compensation capacitors CA, CB and CC added in the low dropout regulators 100 and 200 can be implemented only with a simple combination of transistors and capacitors. Therefore, the aforementioned improvement in PSRR can be achieved without significantly increasing the power consumption of the low dropout regulator.

The above are preferred embodiments of the present disclosure. It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A low dropout regulator, comprising:
an amplifier, comprising a non-inverting input terminal, an inverting input terminal, an internal cascade node and an output terminal;
a buffer circuit, comprising an input terminal and an output terminal, wherein the input terminal of the buffer circuit is coupled to the output terminal of the amplifier;
an output circuit, comprising an input terminal and an output terminal, wherein the input terminal of the output circuit is coupled to the output terminal of the buffer circuit, and the output terminal of the output circuit is configured to output an output voltage;
a first compensation capacitor, coupled between the output terminal of the output circuit and the internal cascade node of the amplifier, and configured to separate a first pole frequency in a Bode plot of the low dropout regulator from a power supply rejection ratio corner frequency of the low dropout regulator; and
a second compensation capacitor, coupled between the input terminal of the buffer circuit and an input power source, and configured to separate a second pole frequency and a third pole frequency in the Bode plot of the low dropout regulator.

2. The low dropout regulator of claim 1, wherein the inverting input terminal of the amplifier is configured to receive a reference voltage, the non-inverting input terminal of the amplifier is configured to receive a feedback voltage, and the amplifier is configured to output a control voltage at the output terminal of the amplifier based on the reference voltage and the feedback voltage, so as to adjust the output voltage of the output circuit.

3. The low dropout regulator of claim 2, wherein the input terminal of the buffer circuit is configured to receive the control voltage, and the buffer circuit is configured to output a buffer voltage at the output terminal of the buffer circuit based on the control voltage.

4. The low dropout regulator of claim 3, wherein the output circuit comprises a power transistor, a control terminal of the power transistor is coupled to the output terminal of the buffer circuit, a first terminal of the power transistor is coupled to the input power source, and a second terminal of the power transistor is coupled to the output terminal of the output circuit.

5. The low dropout regulator of claim 4, wherein the control terminal of the power transistor is configured to receive the buffer voltage.

6. The low dropout regulator of claim 4, wherein the output circuit further comprises a voltage divider circuit, the voltage divider circuit is coupled to the second terminal of the power transistor, the non-inverting input terminal of the amplifier and a ground, and configured to output the feedback voltage to the non-inverting input terminal of the amplifier based on the output voltage.

7. The low dropout regulator of claim 6, wherein the voltage divider circuit comprises a first divider resistor and a second divider resistor, the first divider resistor is coupled between the second terminal of the power transistor and a first node, the second divider resistor is coupled between the first node and the ground, and the non-inverting input terminal of the amplifier is coupled to the first node.

8. The low dropout regulator of claim 1, wherein the first pole frequency in the Bode plot is related to the capacitance of the first compensation capacitor, and
the second pole frequency in the Bode plot is related to the capacitance of the second compensation capacitor.

9. The low dropout regulator of claim 1, wherein in the Bode plot, the first pole frequency is lower than the second pole frequency.

10. A low dropout regulator, comprising:
an amplifier, comprising a non-inverting input terminal, an inverting input terminal, an internal cascade node and an output terminal;
a buffer circuit, comprising an input terminal and an output terminal, wherein the input terminal of the buffer circuit is coupled to the output terminal of the amplifier;
an output circuit, comprising an input terminal and an output terminal, wherein the input terminal of the output circuit is coupled to the output terminal of the buffer circuit, and the output terminal of the output circuit is configured to output an output voltage;
a first compensation capacitor, coupled between the output terminal of the output circuit and the internal cascade node of the amplifier, and configured to separate a first pole frequency in a Bode plot of the low dropout regulator from a power supply rejection ratio corner frequency of the low dropout regulator; and
a second compensation capacitor, coupled between the input terminal and the output terminal of the buffer circuit, and configured to separate a second pole frequency and a third pole frequency in the Bode plot of the low dropout regulator.

11. The low dropout regulator of claim 10, wherein the inverting input terminal of the amplifier is configured to receive a reference voltage, the non-inverting input terminal of the amplifier is configured to receive a feedback voltage, and the amplifier is configured to output a control voltage at the output terminal of the amplifier based on the reference voltage and the feedback voltage, so as to adjust the output voltage of the output circuit.

12. The low dropout regulator of claim 11, wherein the input terminal of the buffer circuit is configured to receive the control voltage, and the buffer circuit is configured to output a buffer voltage at the output terminal of the buffer circuit based on the control voltage.

13. The low dropout regulator of claim 12, wherein the output circuit comprises a power transistor, a control terminal of the power transistor is coupled to the output terminal of the buffer circuit, a first terminal of the power transistor is coupled to an input power source, and a second terminal of the power transistor is coupled to the output terminal of the output circuit.

14. The low dropout regulator of claim 13, wherein the control terminal of the power transistor is configured to receive the buffer voltage.

15. The low dropout regulator of claim 13, wherein the output circuit further comprises a voltage divider circuit, the voltage divider circuit is coupled to the second terminal of the power transistor, the non-inverting input terminal of the amplifier and a ground, and configured to output the feedback voltage to the non-inverting input terminal of the amplifier based on the output voltage.

16. The low dropout regulator of claim 15, wherein the voltage divider circuit comprises a first divider resistor and a second divider resistor, the first divider resistor is coupled between the second terminal of the power transistor and a first node, the second divider resistor is coupled between the first node and the ground, and the non-inverting input terminal of the amplifier is coupled to the first node.

17. The low dropout regulator of claim 10, wherein the first pole frequency in the Bode plot is negatively related to the capacitance of the first compensation capacitor, and
the second pole frequency in the Bode plot is positively related to the capacitance of the first compensation capacitor and negatively related to the capacitance of the second compensation capacitor.

18. The low dropout regulator of claim 10, wherein in the Bode plot, the first pole frequency is lower than the second pole frequency.

19. A capacitor compensation method suitable for a low dropout regulator, wherein the low dropout regulator comprises an amplifier and an output circuit, and the capacitor compensation method comprises:
providing a buffer circuit in the low dropout regulator, wherein the buffer circuit comprises an input terminal and an output terminal, the input terminal of the buffer circuit is coupled to an output terminal of the amplifier, and the output terminal of the buffer circuit is coupled to an input terminal of the output circuit;
providing a first compensation capacitor in the low dropout regulator, wherein the first compensation capacitor is coupled between an output terminal of the output circuit and an internal cascade node of the amplifier, and configured to separate a first pole frequency in a Bode plot of the low dropout regulator and a power supply rejection ratio corner frequency of the low dropout regulator; and
providing a second compensation capacitor in the low dropout regulator, wherein the second compensation capacitor is coupled at the output terminal of the amplifier which is the input terminal of the buffer circuit, and configured to separate a second pole frequency and a third pole frequency in the Bode plot of the low dropout regulator.

20. The capacitor compensation method of claim 19, wherein in the Bode plot, the first pole frequency is lower than the second pole frequency.
